(19) United States
(12) Patent Application Publication
(10) Pub. No.: US 2012/0176002 A1
(43) Pub. Date: Jul. 12, 2012

(54) ACOUSTIC TRANSDUCER AND METHOD OF DRIVING THE SAME

(75) Inventors: Dong-kyun KIM, Suwon-si (KR); Seok-whan CHUNG, Suwon-si (KR); Byung-gil JEONG, Anyang-si (KR)

(73) Assignee: SAMSUNG ELECTRONICS CO., LTD., Suwon-si (KR)

(21) Appl. No.: 13/234,839

(22) Filed: Sep. 16, 2011

(30) Foreign Application Priority Data
Jan. 10, 2011 (KR) 10-2011-0002340

(51) Int. Cl. H01L 41/09; H02N 1/00; H01L 41/04

(52) U.S. Cl. 310/317; 310/334; 310/320; 310/300

(57) ABSTRACT

An acoustic transducer includes a first driving unit group including at least one electrode and a second driving unit group including at least one electrode. The first driving unit group is driven at a first phase, and the second driving unit group is driven at a second phase that is different from the first phase.

### CROSS-REFERENCE TO RELATED APPLICATION

This application claims priority from Korean Patent Application No. 10-2011-0002340, filed on Jan. 10, 2011 in the Korean Intellectual Property Office, the disclosure of which is incorporated herein in its entirety by reference.

### BACKGROUND

1. Field

Apparatuses and methods consistent with embodiments relate to an acoustic transducer and a method of driving the same, and more particularly, to an acoustic transducer having a uniform response characteristic in a broadband frequency spectrum, and a method of driving the same.

2. Description of the Related Art

Research has been conducted on acoustic transducers using micro-electro-mechanical systems (MEMS) technology. An acoustic transducer can be used as a micro-speaker or micro-receiver for personal voice communication and in data communication terminals because of its relatively simple and thin structure. It is important to improve the quality of images obtained by ultrasonic imaging diagnostic apparatuses and to manufacture an ultra-compact transducer. Since micromachined ultrasonic transducers (MUTs) can be fabricated through a process which may be used for processing a semiconductor, MUTs may be integrated into an electronic circuit. MUTs have broadband characteristics as well. Accordingly, an MUT enables a conventional ultrasonic transducer manufactured using a piezoelectric ceramic or a piezoelectric polymer to perform high resolution ultrasonic imaging and three-dimensional (3D) imaging.

A piezoelectric acoustic transducer using MEMS technology generates a sound wave by utilizing a piezoelectric effect, and includes a piezoelectric driving unit that converts an externally applied electric signal into a mechanical vibration. The piezoelectric driving unit may include a piezoelectric device that includes a substrate, a membrane provided on the substrate, and a piezoelectric layer provided between first and second electrodes that are formed on the membrane. When an alternating voltage is applied to the piezoelectric device, the piezoelectric layer deforms. The deformation of the piezoelectric layer may cause vibration of the membrane and thus a sound wave can be generated. An electrostatic acoustic transducer using MEMS technology includes a driving unit that may include a first electrode formed on a substrate, a membrane separated from the first electrode, and a second electrode disposed on the membrane. When a voltage is applied between the first and second electrodes, an electrostatic force is generated. Accordingly, the membrane vibrates and thus a sound wave is generated. Similarly, when a sound wave is incident on the membrane, an electrostatic capacity between the first and second electrodes changes and thus an electric signal is generated.

An acoustic transducer including a single driving unit is limited in obtaining a broadband frequency response characteristic, because a response characteristic in a particular frequency range is determined based on the material used and the shape of the driving unit. In an acoustic transducer including a plurality of driving units having the same frequency response characteristic, there are also limits in obtaining a broadband frequency response characteristic because the same frequency response characteristics are superimposed, and thus a sound pressure is increased only in a particular frequency range.

### SUMMARY

One or more embodiments provide an acoustic transducer that may have a uniform frequency response characteristic in a broadband range, and a method of driving the same.

According to an aspect of an embodiment, there is provided an acoustic transducer including a first driving unit group and a second driving unit group, wherein each of the first driving unit group and the second driving unit group comprises at least one electrode, and wherein the first driving unit group is driven at a first phase and the second driving unit group is driven at a second phase different from the first phase.

The first driving unit group may have frequency response characteristic in a first frequency region and the second driving unit group may have frequency response characteristic in a second frequency region different from the first frequency region. The first frequency region and the second frequency region may be adjacent to each other. The first phase and the second phases may be opposite to each other.

At least one membrane may be disposed between the substrate and the first and second driving unit groups.

The first driving unit group may include at least one first electrode and at least one second electrode, and the second driving unit group may include at least one first electrode and at least one second electrode. The second electrode of the first driving unit group and the first electrode of the second driving unit group may be electrically connected to each other by a first wiring, and the first electrode of the first driving unit group and the second electrode of the second driving unit group may be electrically connected to each other by a second wiring. The first wiring may be connected to one end of an AC power source, and the second wiring may be connected to the other end of the AC power source.

The acoustic transducer may include a phase inversion circuit. The phase inversion circuit may be connected to one of the first and second electrodes of the first driving unit group and the phase inversion circuit may be connected to one of the first and second electrodes of the second driving unit group.

The second electrode of the first driving unit group and the second electrode of the second driving unit group may be integrated to form a common electrode. The acoustic transducer may include a phase inversion circuit connected to one end of a power source. One of the first electrode of the first driving unit group and the first electrode of the second driving unit group may be connected to the phase inversion circuit.

The first driving unit group may include at least one first piezoelectric driving unit, and the second driving unit group may include at least one second piezoelectric driving unit. The first and second piezoelectric driving units may be co-planar. The first and second piezoelectric driving units may be disposed on a membrane disposed on the substrate. Each of the first piezoelectric driving unit and the second piezoelectric driving unit may include a piezoelectric layer disposed between a first electrode and a second electrode. The first piezoelectric driving unit and the second piezoelectric driving unit may be different in at least one of a size and a shape. The first piezoelectric driving unit may include a first mass body, the second piezoelectric driving unit may include a second mass body having a mass different from that of the first mass body.

The first driving unit group may include at least one first electrostatic driving unit, and the second driving unit group may include at least one second electrostatic driving unit. The first electrostatic driving unit may include a first electrode disposed on a membrane and a second electrode disposed on the substrate, and the second electrostatic driving unit may include a first electrode disposed on the membrane and a second electrode disposed on the substrate. The second electrode of the first electrostatic driving unit and the first electrode of the second electrostatic driving unit may be electrically connected to each other by a first wiring connected to one end of a power source, and the first electrode of the first electrostatic driving unit and the second electrode of the second electrostatic driving unit may be electrically connected to each other by a second wiring connected to the other end of the power source. The second electrode of the first electrostatic driving unit and the second electrode of the second electrostatic driving unit may be integrated to form a common electrode on the substrate, and one of the first electrode of the first electrostatic driving unit and the first electrode of the second electrostatic driving unit may be connected to a phase inversion circuit.

A number of driving units in the first driving unit group may be different from a number of driving units in the second driving unit group.

According to an aspect of another embodiment, there is provided an acoustic transducer including a first driving unit group, a second driving unit group and a third driving unit group, wherein each of the first driving unit group, the second driving unit group and the third driving unit group comprises at least one electrode, and wherein the first driving unit group and the third driving unit group are driven at a first phase and the second driving unit group is driven at a second phase different from the first phase.

The first driving unit group may have frequency response characteristic in a first frequency region, the second driving unit group may have frequency response characteristic in a second frequency region different from the first frequency region, and the third driving unit group may have frequency response characteristic in a third frequency region different from the first frequency region and the second frequency region. The first phase and the second phase may be opposite to each other.

According to an aspect of another embodiment, there is provided a method of driving an acoustic transducer which includes a first driving unit group and a second driving unit group, each of the first driving unit group and the second driving unit group comprising at least one electrode, the method including driving the first driving unit group at a first phase and driving the second driving unit group at a second phase different from the first phase.

### BRIEF DESCRIPTION OF THE DRAWINGS

The above and/or other aspects will become apparent and more readily appreciated from the following description of embodiments, taken in conjunction with the accompanying drawings of which:

FIG. 1 is a plan view illustrating an acoustic transducer according to an exemplary embodiment;

FIG. 2 is a cross-sectional view taken along a line II-II′ of FIG. 1;

FIG. 3 shows frequency response characteristics in a same phase driving and an inverse phase driving, where three driving units having frequency response characteristics in different frequency ranges are driven at the same phase in the same phase driving, and one of the three driving units is driven at an inverse phase in the phase inversion driving;

FIG. 4 is a plan view illustrating an acoustic transducer according to an exemplary embodiment;

FIG. 5 is a cross-sectional view illustrating an acoustic transducer according to an exemplary embodiment;

FIG. 6 is a cross-sectional view illustrating an acoustic transducer according to an exemplary embodiment; and

FIG. 7 is a cross-sectional view illustrating an acoustic transducer according to an exemplary embodiment.

### DETAILED DESCRIPTION

Embodiments will now be described in detail with reference to the accompanying drawings, wherein like reference numerals refer to like elements throughout. In the drawings, a size or thickness of each element may be exaggerated for clarity. In this regard, the present embodiments may have different forms and should not be construed as being limited to the descriptions set forth herein.

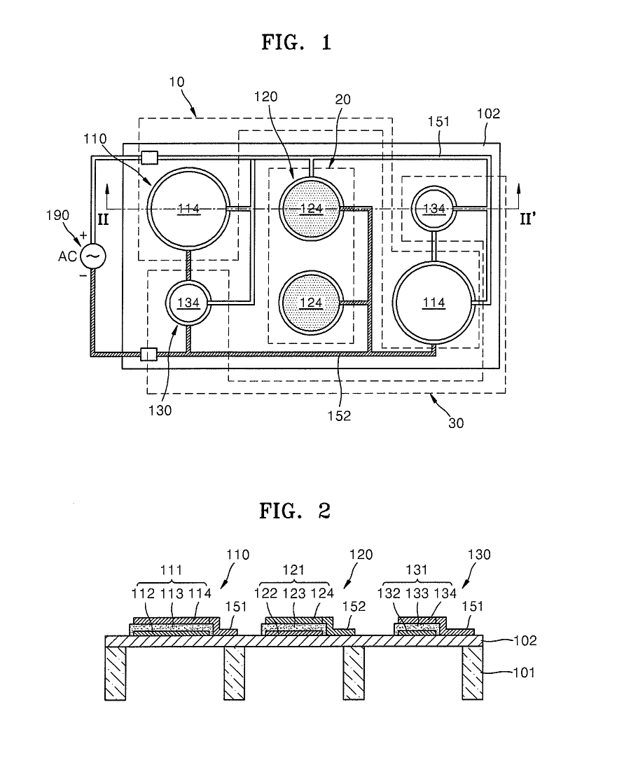

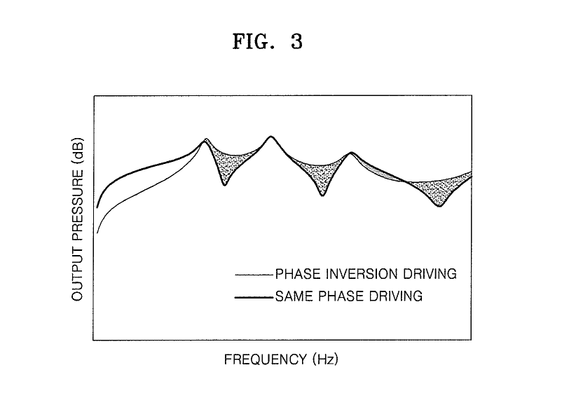

FIG. 1 is a plan view illustrating an acoustic transducer according to an exemplary embodiment. FIG. 2 is a cross-sectional view taken along a line II-II′ of FIG. 1.

Referring to FIGS. 1 and 2, an acoustic transducer includes a plurality of driving unit groups 10, 20, and 30 having different frequency response characteristics. At least one of the driving unit groups 10, 20, and 30 is driven at a phase different from those of the other driving unit groups. For example, the driving unit group 20 may be driven at a phase that is different from those of the driving unit groups 10 and 30. The acoustic transducer of the present exemplary embodiment may be a piezoelectric acoustic transducer. In detail, the acoustic transducer may include the first, second, and third driving unit groups 10, 20, and 30 having frequency response characteristics in different frequency ranges. For example, the first driving unit group 10 may have a frequency response characteristic in a first frequency range that is relatively low. The second driving unit group 20 may have a frequency response characteristic in a second frequency range that is higher than the first frequency range. The third driving unit group 30 may have a frequency response characteristic in a third frequency range that is higher than the second frequency range. The arrangement of the first, second, and third driving unit groups 10, 20, and 30 illustrated in FIG. 1 is an example The first, second, and third driving unit groups 10, 20, and 30 may be arranged in various ways including the arrangement shown in FIG. 1. The acoustic transducer shown in FIG. 1 includes three driving unit groups 10, 20, and 30, but the number of driving unit groups in the acoustic transducer is not limited to three. As an example, the acoustic transducer may include two, four, or more driving unit groups having frequency response characteristics in different frequency ranges.

The first, second, and third driving unit groups 10, 20, and 30 may be provided on a single plane. The first driving unit group 10 may include at least one first piezoelectric driving unit 110. The second driving unit group 20 may include at least one second piezoelectric driving unit 120. The third driving unit group 30 may include at least one third piezoelectric driving unit 130. The first, second, and third piezoelectric driving units 110, 120, and 130 may be provided on a single substrate 101. As an example, the substrate 101 may be a silicon substrate. However, the substrate 101 is not limited to silicon and may be formed of various materials. Referring to FIG. 1, each of the first, second, and third driving unit groups 10, 20, and 30 includes two piezoelectric driving units. (i.e. the first driving unit group 10 including two first piezoelectric driving units 110, the second driving unit group 20 including two second piezoelectric driving units 120, and the third driving unit group 30 including two third piezoelectric driving units 130). However, the number of piezoelectric driving units in each driving unit group may be other than two, and the first, second and third driving unit groups may have different numbers of driving units. For example, each of the first, second, and third driving unit groups 10, 20, and 30 may include one, three, or more piezoelectric driving units. The arrangement of the first, second, and third piezoelectric driving units 110, 120, and 130 illustrated in FIG. 1 is only an example, and thus the first, second, and third piezoelectric driving units 110, 120, and 130 may be arranged in various ways other than the arrangement show in FIG. 1.

Referring to FIG. 2, the first piezoelectric driving unit 110 may include a membrane 102 formed on the substrate 101 and the first, second, and third piezoelectric devices 111, 121, and 131 provided on the membrane 102. The first piezoelectric device 111 may include a first electrode 112, a first piezoelectric layer 113, and a second electrode 114 that are sequentially disposed on the membrane 102. The second piezoelectric driving unit 120 may include the membrane 102 and a second piezoelectric device 121 provided on the membrane 102. The second piezoelectric device 121 may include a first electrode 122, a second piezoelectric layer 123, and a second electrode 124 that are sequentially disposed on the membrane 102. The third piezoelectric driving unit 130 may include the membrane 102 and a third piezoelectric device 131 provided on the membrane 102. The third piezoelectric device 131 may include a first electrode 132, a third piezoelectric layer 133, and a second electrode 134 that are sequentially disposed on the membrane 102.

The first, second, and third piezoelectric driving units 110, 120, and 130 may have different sizes in order to have frequency response characteristics in different frequency ranges. For example, the first piezoelectric driving unit 110 may have a larger size than those of the second and third piezoelectric driving units 120 and 130. The first piezoelectric driving unit 110 may have a frequency response characteristic in a first frequency range that is relatively low. The second piezoelectric driving unit 120 may be smaller than the first piezoelectric driving unit 110, but larger than the third piezoelectric driving unit 130. The second piezoelectric driving unit 120 may have a frequency response characteristic in a second frequency range that is higher than the first frequency range. The third piezoelectric driving unit 130 may be smaller than the second piezoelectric driving unit 120, and the third piezoelectric driving unit 130 may have a frequency response characteristic in a third frequency range that is higher than the second frequency range.

According to exemplary embodiments, at least one of the first, second, and third piezoelectric driving units 110, 120, and 130 may be driven at a phase different from that of the other driving groups. For example, the second piezoelectric driving unit 120 may be driven at a phase different from the first and third piezoelectric driving units 110 and 130. For example, piezoelectric driving units having frequency response characteristics in frequency ranges adjacent to each other may be driven at opposite phases. Accordingly, the first and third piezoelectric driving units 110 and 130 may be driven at the same phase, whereas the second piezoelectric driving unit 120 may be driven at a phase opposite to that of the first and third piezoelectric driving units 110 and 130.

According to a wiring configuration illustrated in FIGS. 1 and 2, the first, second, and third piezoelectric driving units 110, 120, and 130 may be driven by a single AC power source 190. For example, the second electrodes 114 and 134 of the first and third piezoelectric driving units 110 and 130 may be electrically connected to each other by a first wiring 151 that is connected to one end of the AC power source 190. In the second piezoelectric driving unit 120, the first electrode 122 may be electrically connected to the second electrodes 114 and 134 of the first and third piezoelectric driving units 110 and 130 through the first wiring 151. Accordingly, the second electrode 114 of the first piezoelectric driving unit 110, the first electrode 122 of the second piezoelectric driving unit 120, and the second electrode 134 of the third piezoelectric driving unit 130 may be electrically connected to one another by the first wiring 151. The first electrodes 112 and 132 of the first and third piezoelectric driving units 110 and 130 and the second electrode 124 of the second piezoelectric driving unit 120 may be electrically connected to each other by a second wiring 152 that is connected to the other end of the AC power source 190. When the electrodes 114, 122 and 134 are electrically connected to each other through the first wiring 151, the first electrode 112 of the first piezoelectric driving unit 110, the second electrode 124 of the second piezoelectric driving unit 120, and the first electrode 132 of the third piezoelectric driving unit 130 are electrically connected to one another by the second wiring 152. When a voltage is applied from the AC power source 190 to the acoustic transducer, the first and third piezoelectric driving units 110 and 130 are driven at the same phase, whereas the second piezoelectric driving unit 120 is driven at a phase opposite to that of the first and third piezoelectric driving units 110 and 130. Alternatively, the first, second, and third piezoelectric driving units 110, 120, and 130 may be driven by separate power sources.

In a piezoelectric driving unit (e.g. the first piezoelectric driving unit 110), the phase of the membrane of the piezoelectric driving unit (e.g. the membrane 102) and the phase of the sound pressure output by the membrane may be different at frequencies below a resonant frequency of the piezoelectric driving unit (e.g. the first piezoelectric driving unit 110), as compared to frequencies above the resonant frequency. Therefore, when the first and second piezoelectric driving units 110 and 120 having frequency response characteristics in frequency ranges adjacent to each other are driven at the same phase, there may be a dip phenomenon in which a total output sound pressure is considerably decreased. At frequencies lower than the resonant frequency of the first piezoelectric driving unit 110, a phase of a sound pressure output by the first piezoelectric driving unit 110 is the same as that of a sound pressure output by the second piezoelectric driving unit 120, and thus a total output sound pressure is increased. However, at frequencies higher than the resonant frequency of the first piezoelectric driving unit 110, the phase of the sound pressure output by the first piezoelectric driving unit 110 may be different from and opposite the sound pressure output at frequencies lower than the resonant frequency of the first driving unit 110. Thus, at frequencies higher than the resonance frequency of the first driving unit 110, the phase of the sound pressure output by the first piezoelectric driving unit 110 is opposite to the phase of the sound pressure output by the second piezoelectric driving unit 120. Accordingly, the sound pressure output by the first piezoelectric driving unit 110 and the sound pressure output by the second piezoelectric driving unit 120 offset each other, and thus the dip phenomenon in which the total output sound pressure is decreased is generated.

According to an exemplary embodiment, the second piezoelectric driving unit 120 is driven at a phase opposite to that of the first piezoelectric driving unit 110 in order to address the above dip phenomenon problem. When the second piezoelectric driving unit 120 is driven at the inversed phase, the sound pressure output by the first piezoelectric driving unit 110 and the sound pressure output by the second piezoelectric driving unit 120 constructively interfere with each other at the frequencies higher than the resonant frequency of the first piezoelectric driving unit 110, and thus a relatively uniform frequency response characteristic from the first frequency range to the second frequency range may be obtained.

When driving the second piezoelectric driving unit at the inversed phase, at the frequencies lower than the resonant frequency of the first piezoelectric driving unit 110, the phase of the sound pressure output by the first piezoelectric driving unit 110 and the phase of the sound pressure output by the second piezoelectric driving unit 120 are opposite to each other. However, a relatively uniform frequency response characteristic may be obtained at the frequencies lower than the resonant frequency of the first piezoelectric driving unit 110, because the sound pressure output by the first piezoelectric driving unit 110 is much higher than the sound pressure output by the second piezoelectric driving unit 120.

FIG. 3 illustrates output sound pressures with respect to frequency of an acoustic transducer in a same phase driving and a phase inversion driving. According to exemplary embodiments, three (i.e. first, second and third) piezoelectric driving units may have frequency response characteristics in first, second, and third frequency ranges that are different from one another. According to same phase driving, the three piezoelectric driving units are driven at the same phase. On the other hand, one of the three piezoelectric driving units, for example the second piezoelectric driving unit having the frequency characteristics in the second frequency range, may be driven at a phase opposite to that of the other (i.e. first and third) piezoelectric driving units according to phase inversion driving. Referring to FIG. 3, in same phase driving, a total output sound pressure may be reduced because dip phenomena may be observed between the first frequency range and the second frequency range, and between the second frequency range and the third frequency range. However, in phase inversion driving, it can be seen that a relatively uniform frequency response characteristic may be obtained over the entire frequency range from the first frequency range of the first piezoelectric driving unit to the third frequency range of the third piezoelectric driving unit, as shown in FIG. 3.

According to the exemplary embodiment shown in FIGS. 1 and 2, the first, second, and third piezoelectric driving units 110, 120, and 130 have different sizes and provide frequency response characteristics in different frequency ranges. However, piezoelectric driving units having frequency response characteristics in different frequency ranges may be obtained by using any of a variety of methods.

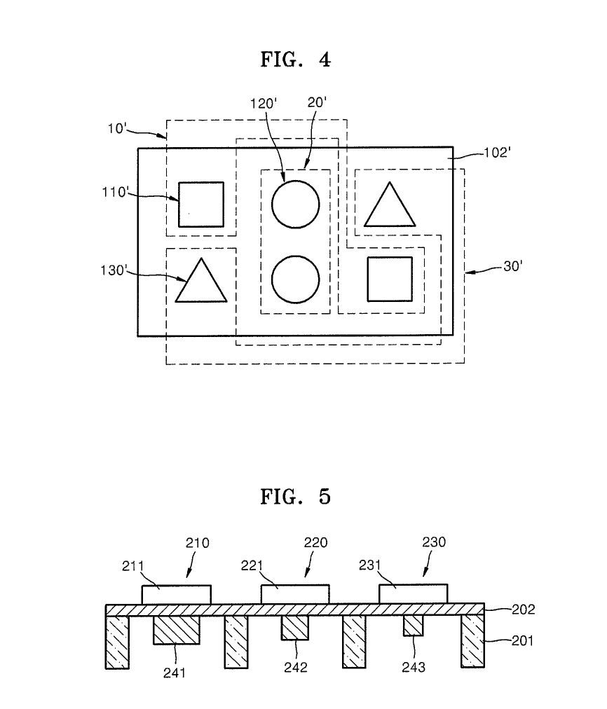

FIG. 4 is a plan view illustrating an acoustic transducer according to an embodiment. The following description will focus on technical features of the present exemplary embodiment that are different from the previously described exemplary embodiments.

Referring to FIG. 4, an acoustic transducer may include first, second, and third driving unit groups 10′, 20′, and 30′ having frequency response characteristics in different frequency ranges. For example, the first driving unit group 10′ may have a frequency response characteristic in a first frequency range that is relatively low. The second driving unit group 20′ may have a frequency response characteristic in a second frequency range that is higher than the first frequency range. The third driving unit group 30′ may have a frequency response characteristic in a third frequency range that is higher than the second frequency range. The first and third driving unit groups 10′ and 30′ may be driven at the same phase, and the second driving unit group 20′ may be driven at a phase opposite to that of the first and second driving unit groups 10′ and 30′ as described in the exemplary embodiment of FIG. 1. The first, second, and third driving unit groups 10′, 20′, and 30′ may be arranged in various ways. The number of driving unit groups in the acoustic transducer may be varied, as well.

The first driving unit group 10′ may include at least one first piezoelectric driving unit 110′. The second driving unit group 20′ may include at least one second piezoelectric driving unit 120′. The third driving unit group 30′ may include at least one third piezoelectric driving unit 130′. The first, second, and third piezoelectric driving units 110′, 120′, and 130′ may be provided on a single substrate (not shown). Referring to FIG. 4, a membrane 102′ may be formed on the substrate. The first, second, and third piezoelectric driving units 110′, 120′, and 130′ may have similar sizes, as shown in FIG. 4, but the shapes of the first, second, and third piezoelectric driving units 110′, 120′, and 130′ may be different from one another. Therefore, each of the first, second and third piezoelectric driving units 110′, 120′, and 130′ may provide frequency response characteristics in different frequency ranges. For example, the first piezoelectric driving unit 110′ may have a rectangular shape, the second piezoelectric driving unit 120′ may have a circular shape, and the third piezoelectric driving unit 130′ may have a triangular shape. The above configuration is only an example, and thus the first, second, and third piezoelectric driving units 110′, 120′, and 130′ may have a variety of different shapes.

The number of the first, second, and third piezoelectric driving units 110′, 120′, and 130′ in the corresponding first, second, and third driving unit groups 10′, 20′, and 30′ may vary. The arrangement of the first, second, and third piezoelectric driving units 110′, 120′, and 130′ illustrated in FIG. 4 may be modified in various ways. Since structures of the first, second, and third piezoelectric driving units 110′, 120′, and 130′ are the same as those of the exemplary embodiment shown in FIG. 2, a detailed description thereof will be omitted herein. Referring to FIG. 4, the first, second, and third piezoelectric driving units 110′, 120′, and 130′ have the same (or substantially similar) size, but different shapes. However, it is also possible that the first, second, and third piezoelectric driving units 110′, 120′, and 130′ may have different shapes and different sizes, as well.

FIG. 5 is a cross-sectional view illustrating an acoustic transducer according to an exemplary embodiment. The following description will focus on technical features of the present exemplary embodiment that are different from those of the previously described exemplary embodiments.

Referring to FIG. 5, an acoustic transducer may include first, second, and third driving unit groups having frequency response characteristics in different frequency ranges. For example, the first driving unit group may have a frequency response characteristic in a first frequency range that is relatively low. The second driving unit group may have a frequency response characteristic in a second frequency range that is higher than the first frequency range. The third driving unit group may have a frequency response characteristic in a third frequency range that is higher than the second frequency range. The first and third driving unit groups are driven at the same phase and the second driving unit group is driven at a phase that is different from that of the first and second driving unit groups. For example, the phase of the second driving unit group may be opposite to the phase of the first and third driving unit groups. The first, second, and third driving unit groups may be arranged in various ways. The number of driving unit groups in the acoustic transducer of the present embodiment may be varied, as well.

The first driving unit group may include at least one first piezoelectric driving unit 210. The second driving unit group may include at least one second piezoelectric driving unit 220. The third driving unit group may include at least one third piezoelectric driving unit 230. The first, second, and third piezoelectric driving units 210, 220, and 230 may be provided on a single substrate 201. Referring to FIG. 5, the first, second, and third piezoelectric driving units 210, 220, and 230 may have substantially the same size. However, the first, second, and third piezoelectric driving units 210, 220, and 230 may include mass bodies 241, 242, and 243 having different weights, and thus the first, second and third piezoelectric driving units 210, 220 and 230 may provide frequency response characteristics in different frequency ranges.

For example, the first piezoelectric driving unit 210 may include a membrane 202 formed on the substrate 201. A first piezoelectric device 211 may be provided on an upper surface of the membrane 202, and a first mass body 241 may be provided on a lower surface of the membrane 202. The second piezoelectric driving unit 220 may include the membrane 202, a second piezoelectric device 221 may be provided on the upper surface of the membrane 202, and a second mass body 242 may be provided on the lower surface of the membrane 202. The third piezoelectric driving unit 210 may include the membrane 202, a third piezoelectric device 231 may be provided on the upper surface of the membrane 202, and a third mass body 243 may be provided on the lower surface of the membrane 202. The first mass body 241 may be heavier than the second and third mass bodies 242 and 243. The second mass body 242 may be lighter than the first mass body 241 and heavier than the third mass body 243. The third mass body 243 is lighter than the second mass body 242. thus, the first, second, and third piezoelectric driving units 210, 220, and 230 may include the first, second and third mass bodies 241, 242, and 243 having different weights, and accordingly, the first, second and third piezoelectric driving units 210, 220 and 230 may provide frequency response characteristics in different frequency ranges.

According to exemplary embodiments, the first, second, and third piezoelectric driving units may have frequency response characteristics in different frequency ranges by using any of a variety of methods, in addition to the above-described methods. For example, the first, second, and third piezoelectric driving units may include membranes of the same size, and may provide frequency response characteristics in different frequency ranges by employing piezoelectric layers of different sizes.

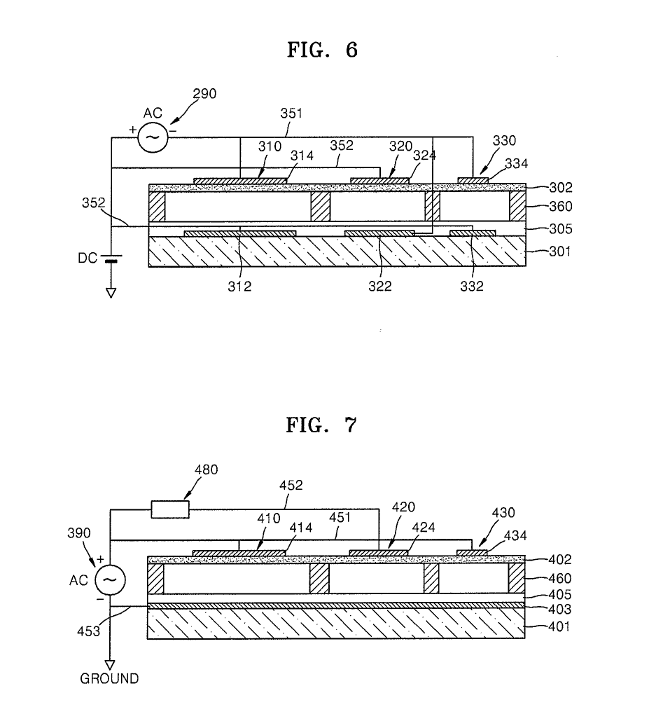

FIG. 6 is a cross-sectional view illustrating an acoustic transducer according to an exemplary embodiment. The following description will focus on the technical features of the present exemplary embodiment that are different from the previously described exemplary embodiments. The acoustic transducer according to the present embodiment may be an electrostatic ultrasonic transducer.

Referring to FIG. 6, the acoustic transducer according to the present embodiment may include a plurality of driving unit groups having frequency response characteristics in different frequency ranges. At least one of the driving unit groups may be driven at a phase different from those of the other driving unit groups. For example, the acoustic transducer may include first, second, and third driving unit groups having frequency response characteristics in different frequency ranges and being arranged in a manner similar to the arrangement in the exemplary embodiment shown in FIG. 1. However, the above configuration is only an example, and the acoustic transducer may include a various number of driving unit groups, and the driving unit groups may be arranged in various ways.

According to the exemplary embodiment shown in FIG. 6, the first driving unit group may have a frequency response characteristic in a first frequency range that is relatively low. The second driving unit group may have a frequency response characteristic in a second frequency range that is higher than the first frequency range. The third driving unit group may have a frequency response characteristic in a third frequency range that is higher than the second frequency range. The first, second, and third driving unit groups may be provided on a single plane. The first driving unit group may include at least one first electrostatic driving unit 310. The second driving unit group may include at least one second electrostatic driving unit 320. The third driving unit group may include at least one third electrostatic driving unit 330. The first, second, and third electrostatic driving units 310, 320, and 330 may be provided on a single substrate 301. As an example, the substrate 301 may be a silicon substrate, but the substrate 301 is not limited to the silicon substrate and the substrate 301 may be formed of various materials.

Referring to FIG. 6, the first electrostatic driving unit 310 may include a first electrode 312 formed on the substrate 301, a membrane 302 provided separately from the first electrode 312, and a second electrode 314 provided on the membrane 302. The second electrostatic driving unit 320 may include a first electrode 322 formed on the substrate 301 at a predetermined distance from the first electrode 312 of the first electrostatic driving unit 310, the membrane 302 provided separately from the first electrode 322, and a second electrode 324 provided on the membrane 302 at a predetermined distance from the second electrode 314 of the first electrostatic driving unit 310. The third electrostatic driving unit 330 may include a first electrode 332 formed on the substrate 301 at a predetermined distance from the first electrode 312 of the first electrostatic driving unit 310 and at a predetermined distance from the first electrode 322 of the second electrostatic driving unit 320, the membrane 302 provided separately from the first electrode 332, and a second electrode 334 provided on the membrane 302 at a predetermined distance from the second electrode 314 of the first electrostatic driving unit 310 and at a predetermined distance from the second electrode 324 of the second electrostatic driving unit 320. Referring to FIG. 6 a dielectric layer 305 may be formed on the substrate 301 to cover the first electrodes 312, 322, and 332. A plurality of partition walls 360 may be provided between the first, second, and third driving units 310, 320, and 330 respectively.

The first, second, and third electrostatic driving units 310, 320, and 330 may have different sizes in order to have frequency response characteristics in different frequency ranges. In detail, the first electrostatic driving unit 310 may have a larger size than those of the second and third electrostatic driving units 320 and 330, and thus the first electrostatic driving unit 310 may have a frequency response characteristic in a first frequency range that is relatively low. The size of the second electrostatic driving unit 320 may be smaller than that of the first electrostatic driving unit 310, but larger than that of the third electrostatic driving unit 330. The second electrostatic driving unit 320 may have a frequency response characteristic in a second frequency range that is higher than the first frequency range. The size of the third electrostatic driving unit 330 may be smaller than that of the second electrostatic driving unit 320 and may have a frequency response characteristic in a third frequency range that is higher than the second frequency range.

At least one of the first, second, and third electrostatic driving units 310, 320, and 330 may be driven at a phase different from that of the other driving units. For example, the second electrostatic driving unit 320 may be driven at a phase that is opposite to that of the first and third electrostatic driving units 310 and 330. For example, electrostatic driving units having frequency response characteristics in frequency ranges adjacent to each other may be driven at opposite phases. Accordingly, the first and third electrostatic driving units 310 and 330 are driven at the same phase, whereas the second electrostatic driving unit 320 may be driven at a phase opposite to that of the first and third electrostatic driving units 310 and 330.

Referring to FIG. 6, the first, second, and third electrostatic driving units 310, 320, and 330 may be driven by a single AC power source 290. For example, the second electrodes 314 and 334 of the first and third electrostatic driving units 310 and 330 may be electrically connected to each other by a first wiring 351 that is connected to one end of the AC power source 290. In the second electrostatic driving unit 320, the first electrode 322 may be electrically connected to the second electrodes 314 and 334 of the first and third electrostatic driving units 310 and 330 through the first wiring 351. Accordingly, the second electrode 314 of the first electrostatic driving unit 310, the first electrode 322 of the second electrostatic driving unit 320, and the second electrode 334 of the third electrostatic driving unit 330 may be electrically connected to one another by the first wiring 351. The first electrodes 312 and 332 of the first and third electrostatic driving units 310 and 330 and the second electrode 324 of the second electrostatic driving unit 320 may be electrically connected to each other by a second wiring 352 that is connected to the other end of the AC power source 290. When the electrodes 314, 322 and 334 are electrically connected to each other through the first wiring 351, the first electrode 312 of the first electrostatic driving unit 310, the second electrode 324 of the second electrostatic driving unit 320, and the first electrode 332 of the third electrostatic driving unit 330 are electrically connected to one another by the second wiring 352. When a voltage is applied from the AC power source 290 to the acoustic transducer, the first and third electrostatic driving units 310 and 330 may be driven at the same phase, whereas the second electrostatic driving unit 320 may be driven at a phase that is opposite to that of the first and third electrostatic driving units 310 and 330. Alternatively, the first, second, and third electrostatic driving units 310, 320, and 330 each may be driven by separate power sources.

As such, when the first and third electrostatic driving units 310 and 330 are driven at the same phase and the second electrostatic driving unit 320 is driven at a phase opposite to that of the first and third electrostatic driving units 310 and 330, a uniform frequency response characteristic in a broadband range may be obtained as described above.

According to the present exemplary embodiment of the invention, the first, second, and third electrostatic driving units 310, 320, and 330 have different sizes and provide frequency response characteristics in different frequency ranges. However, the first, second, and third electrostatic driving units 310, 320, and 330 may also have frequency response characteristics in different frequency ranges by various methods including shape change of the electrostatic driving units, and shape and size modification of the electrostatic driving units. It may be also possible that the first, second, and third electrostatic driving units 310, 320, and 330 may have frequency response characteristics in different frequency ranges by including mass bodies having different weights.

FIG. 7 is a cross-sectional view illustrating an acoustic transducer according to an exemplary embodiment. The following description will focus on technical features of the present exemplary embodiment different from the previously described exemplary embodiments.

Referring to FIG. 7, the acoustic transducer according to the present embodiment may include a plurality of driving unit groups having frequency response characteristics in different frequency ranges. At least one of the driving unit groups may be driven at a phase different from those of the other driving unit groups. For example, the acoustic transducer may include first, second, and third driving unit groups having frequency response characteristics in different frequency ranges and being arranged in a manner similar to the arrangement in the exemplary embodiment shown in FIG. 1. However, the above configuration is only an example, and thus the acoustic transducer may include a various number of driving unit groups, and the driving unit groups may be arranged in various configurations.

According to the exemplary embodiment shown in FIG. 7, the first driving unit group may have a frequency response characteristic in a first frequency range that is relatively low. The second driving unit group may have a frequency response characteristic in a second frequency range that is higher than the first frequency range. The third driving unit group may have a frequency response characteristic in a third frequency range that is higher than the second frequency range. The first, second, and third driving unit groups may be provided on a single plane. The first driving unit group may include at least one first electrostatic driving unit 410. The second driving unit group may include at least one second electrostatic driving unit 420. The third driving unit group may include at least one third electrostatic driving unit 430. The first, second, and third electrostatic driving units 410, 420, and 430 may be provided on a single substrate 401.

Referring to FIG. 7, the first electrostatic driving unit 410 may include a first electrode 403 that may be a common electrode and formed on the substrate 401, a membrane 402 provided separately from the first electrode 403, and a second electrode 414 provided on the membrane 402. The second electrostatic driving unit 420 may include the first electrode 403, the membrane 402, and a second electrode 424 provided on the membrane 402 at a predetermined distance from the second electrode 414 of the first electrostatic driving unit 410. The third electrostatic driving unit 430 may include the first electrode 403, the membrane 402, and a second electrode 434 provided on the membrane 402 at a predetermined distance from the second electrode 414 of the first electrostatic driving unit 410 and at a predetermined distance from the second electrode 424 of the second electrostatic driving unit 420. Referring to FIG. 6, a dielectric layer 405 may be formed on the substrate 401 to cover the first electrode 403. A plurality of partition walls 460 may be provided between the first, second, and third driving units 410, 420, and 430.

The first, second, and third electrostatic driving units 410, 420, and 430 may have different sizes in order to have frequency response characteristics in different frequency ranges. In detail, the first electrostatic driving unit 410 may have a larger size than those of the second and third electrostatic driving units 420 and 430, and thus the first electrostatic driving unit 410 may have a frequency response characteristic in a first frequency range that is relatively low. The size of the second electrostatic driving unit 420 may be smaller than that of the first electrostatic driving unit 410, but larger than the third electrostatic driving unit 430 in and may have a frequency response characteristic in a second frequency range that is higher than the first frequency range. The size of the third electrostatic driving unit 430 may be smaller than that of the second electrostatic driving unit 420 and may have a frequency response characteristic in a third frequency range that is higher than the second frequency range.

At least one of the first, second, and third electrostatic driving units 410, 420, and 430 may be driven at a phase that is different from that of the other driving units. For example, the second electrostatic driving unit 420 may be driven at a phase that is opposite to that of the first and third electrostatic driving units 410 and 430. In detail, electrostatic driving units having frequency response characteristics in frequency ranges adjacent to each other may be driven at opposite phases. Accordingly, the first and third electrostatic driving units 410 and 430 are driven at the same phase, whereas the second electrostatic driving unit 420 may be driven at a phase opposite to that of the first and third electrostatic driving units 410 and 430.

Referring to FIG. 7, the first, second, and third electrostatic driving units 410, 420, and 430 may be driven by a single AC power source 390. In detail, the second electrodes 414 and 434 of the first and third electrostatic driving units 410 and 430 may be electrically connected to each other by a first wiring 451 that is connected to one end of the AC power source 390. The second electrode 424 of the second electrostatic driving unit 420 may be electrically connected by a second wiring 452 that includes a phase inversion circuit 480. The second wiring 452 may be connected to the end of the AC power source 390 to which the first wiring 451 is connected. The first electrode 403 is electrically connected to a third wiring 453 that is connected to the other end of the AC power source 390. It may be also possible to connect the second wiring 452 to the other end of the AC power source 390 instead of using the phase inversion circuit 480. The third wiring 453 may be grounded. Thus, when a voltage is applied from the AC power source 390 to the acoustic transducer, the first and third electrostatic driving units 410 and 430 are driven at the same phase, whereas the second electrostatic driving unit 420 may be driven at a phase that is opposite to that of the first and third electrostatic driving units 410 and 430. Alternatively, the first, second, and third electrostatic driving units 410, 420, and 430 each may be driven by separate power sources.

As such, when the first and third electrostatic driving units 410 and 430 are driven at the same phase and the second electrostatic driving unit 420 is driven at the phase opposite to that of the first and third electrostatic driving units 410 and 430, a relatively uniform frequency response characteristic in a broadband range can be obtained. According to the present exemplary embodiment, the first, second, and third electrostatic driving units 410, 420, and 430 have different sizes and provide frequency response characteristics in different frequency ranges. However, the first, second, and third electrostatic driving units 410, 420, and 430 may have frequency response characteristics in different frequency ranges by various methods including shape change of the electrostatic driving units, and shape and size modification of the electrostatic driving units. It may be also possible that the first, second, and third electrostatic driving units 410, 420, and 430 may have frequency response characteristics in different frequency ranges by including mass bodies having different weights.

As described above, according to the one or more of the above embodiments, since the acoustic transducer includes a plurality of driving unit groups having frequency response characteristics in different frequency ranges and at least one of the driving unit groups is driven at a phase different from that of the other driving unit groups, a uniform frequency response characteristic may be obtained in a broadband range. It should be understood that the exemplary embodiments described therein should be considered in a descriptive sense only and not for purposes of limitation. Descriptions of features or aspects within each embodiment should typically be considered as available for other similar features or aspects in other embodiments.

While exemplary embodiments have been particularly shown and described herein, it will be understood by one of ordinary skill in the art that various changes in form and details may be made therein without departing from the spirit and scope of the inventive concept as defined by the following claims.

What is claimed is:

1. An acoustic transducer comprising;
a substrate;
a first driving unit group disposed on the substrate; and
a second driving unit group disposed on the substrate,
wherein each of the first driving unit group and the second driving unit group comprises at least one electrode, and
wherein the first driving unit group is driven at a first phase, and the second driving unit group is driven at a second phase which is different from the first phase.

2. The acoustic transducer of claim 1, wherein the first driving unit group has a frequency response characteristic in a first frequency region, and the second driving unit group has a frequency response characteristic in a second frequency region which is different from the first frequency region.

3. The acoustic transducer of claim 2, wherein the first frequency region and the second frequency region are adjacent to each other.

4. The acoustic transducer of claim 1, wherein the first phase and the second phase are opposite to each other.

5. The acoustic transducer of claim 1, further comprising at least one membrane disposed between the substrate and the first driving unit group and the second driving unit group.

6. The acoustic transducer of claim 1, wherein
the first driving unit group comprises at least one first electrode and at least one second electrode; and
the second driving unit group comprises at least one first electrode and at least one second electrode.

7. The acoustic transducer of claim 6, further comprising:
a first wiring which is electrically connected to the second electrode of the first driving unit group and the first electrode of the second driving unit group; and
a second wiring which is electrically connected to the first electrode of the first driving unit group and the second electrode of the second driving unit group.

8. The acoustic transducer of claim 7, wherein the first wiring is further connected to a first end of an AC power source, and the second wiring is further connected to a second end of the AC power source

9. The acoustic transducer of claim 6, further comprising a phase inversion circuit which is connected to one of the first and second electrodes of the first driving unit group and is connected to one of the first and second electrodes of the second driving unit group.

10. The acoustic transducer of claim 6, wherein the second electrode of the first driving unit group and the second electrode of the second driving unit group together comprise a single common electrode.

11. The acoustic transducer of claim 10, further comprising:
a power source; and
a phase inversion circuit connected to the power source and one of the first electrode of the first driving unit group and the first electrode of the second driving unit group.

12. The acoustic transducer of claim 1, wherein the first driving unit group comprises at least one first piezoelectric driving unit, and the second driving unit group comprises at least one second piezoelectric driving unit.

13. The acoustic transducer of claim 12, wherein the first piezoelectric driving unit and the second piezoelectric driving unit are co-planar.

14. The acoustic transducer of claim 12, further comprising a membrane disposed on the substrate, wherein the first piezoelectric driving unit and the second piezoelectric driving unit are disposed on the membrane.

15. The acoustic transducer of claim 12, wherein the first piezoelectric driving unit comprises a piezoelectric layer disposed between the first electrode and the second electrode of the first driving unit group, and the second piezoelectric driving unit comprises a piezoelectric layer disposed between the first electrode and the second electrode.

16. The acoustic transducer of claim 12, wherein at least one of a size and a shape of the first piezoelectric driving unit is different from that of the second piezoelectric driving unit.

17. The acoustic transducer of claim 12, wherein the first piezoelectric driving unit comprises a first mass body, and the second piezoelectric driving unit comprises a second mass body having a weight that is different from a weight of the first mass body.

18. The acoustic transducer of claim 1, wherein the first driving unit group comprises at least one first electrostatic driving unit, and the second driving unit group comprises at least one second electrostatic driving unit.

19. The acoustic transducer of claim 18, further comprising a membrane, wherein
the first electrostatic driving unit comprises a first electrode disposed on the membrane and a second electrode disposed on the substrate, and
the second electrostatic driving unit comprises a first electrode disposed on the membrane and a second electrode disposed on the substrate.

20. The acoustic transducer of claim 19, further comprising:
a power source;
a first wiring which is electrically connected to the second electrode of the first electrostatic driving unit, the first electrode of the second electrostatic driving unit, and a first end of the power source; and
a second wiring which is electrically connected to the first electrode of the first electrostatic driving unit, the second electrode of the second electrostatic driving unit, and a second end of the power source.

21. The acoustic transducer of claim 19, further comprising a phase inversion circuit, wherein
one of the first electrode of the first electrostatic driving unit and the first electrode of the second electrostatic driving unit is connected to the phase inversion circuit; and
the second electrode of the first electrostatic driving unit and the second electrode of the second electrostatic driving unit together comprise a single a common electrode disposed on the substrate.

22. The acoustic transducer of claim 1, wherein the first driving unit group comprises a first number of driving units and the second driving unit group comprises a second number of driving units different from the first number.

23. An acoustic transducer comprising:
a substrate;
a first driving unit group disposed on the substrate;
a second driving unit group disposed on the substrate; and
a third driving unit group disposed on the substrate,
wherein each of the first driving unit group, the second driving unit group and the third driving unit group comprises at least one electrode, and
wherein the first driving unit group and the third driving unit group are driven at a first phase, and the second driving unit group is driven at a second phase that is different from the first phase.

24. The acoustic transducer of claim 23, wherein the first driving unit group has frequency response characteristic in a first frequency region, the second driving unit group has frequency response characteristic in a second frequency region that is different from the first frequency region, and the third driving unit group has frequency response characteristic in a third frequency region that is different from the first frequency region and the second frequency region.

25. The acoustic transducer of claim 24, wherein the first phase and the second phase are opposite to each other.

26. A method of driving an acoustic transducer that comprises a first driving unit group and a second driving unit group, each of the first driving unit group and the second driving unit group comprising at least one electrode, the method comprising:
driving the first driving unit group at a first phase; and
driving the second driving unit group at a second phase that is different from the first phase.

27. The method of claim 26, wherein the first driving unit group has frequency response characteristic in a first frequency region, and the second driving unit group has frequency response characteristic in a second frequency region that is different from the first frequency region.

28. The method of claim 27, wherein the first frequency region and the second frequency region are adjacent to each other.

29. The method of claim 26, wherein the first phase and the second phase are opposite to each other.

30. The method of claim 26, wherein the acoustic transducer further comprises at least one membrane disposed between the substrate and the first driving unit group and the second driving unit group.

31. The method of claim 26, wherein
the first driving unit group comprises at least one first electrode and at least one second electrode; and
the second driving unit group comprises at least one first electrode and at least one second electrode.

32. The method of claim 31, wherein the acoustic transducer further comprises:
a first wiring which is electrically connected to the second electrode of the first driving unit group and the first electrode of the second driving unit group; and
a second wiring which is electrically connected to the first electrode of the first driving unit group and the second electrode of the second driving unit group.

33. The method of claim 32, wherein the first wiring is further connected to a first end of an AC power source, and the second wiring is further connected to a second end of the AC power source

34. The method of claim 31, wherein the acoustic transducer further comprises a phase inversion circuit that is connected to one of the first and second electrodes of the first driving unit group, and is connected to one of the first and second electrodes of the second driving unit group.

35. The method of claim 31, wherein the second electrode of the first driving unit group and the second electrode of the second driving unit group together comprise a single common electrode.

36. The method of claim 35, wherein the acoustic transducer further comprises a power source and a phase inversion circuit connected to the power source and one of the first electrode of the first driving unit group and the first electrode of the second driving unit group.

37. The method of claim 26, wherein the first driving unit group comprises at least one first piezoelectric driving unit, and the second driving unit group comprises at least one second piezoelectric driving unit.

38. The method of claim 37, wherein the first piezoelectric driving unit and the second piezoelectric driving unit are co-planar.

39. The method of claim 37, wherein the acoustic transducer further comprises a membrane disposed on the substrate, wherein the first piezoelectric driving unit and the second piezoelectric driving unit are disposed on the membrane.

40. The method of claim 37, wherein the first piezoelectric driving unit comprises a piezoelectric layer disposed between the first electrode and the second electrode of the first driving unit group, and the second piezoelectric driving unit comprises a piezoelectric layer disposed between the first electrode and the second electrode

41. The method of claim 37, wherein at least one of a size and a shape of the first piezoelectric driving unit is different from that of the second piezoelectric driving unit.

42. The method of claim 37, wherein the first piezoelectric driving unit comprises a first mass body and the second piezoelectric driving unit comprises a second mass body having a weight different from a weight of the first mass body.

43. The method of claim 26, wherein the first driving unit group comprises at least one first electrostatic driving unit, and the second driving unit group comprises at least one second electrostatic driving unit.

44. The method of claim 37, wherein
the acoustic transducer further comprises a membrane,
the first electrostatic driving unit comprises a first electrode disposed on the membrane and a second electrode disposed on the substrate, and
the second electrostatic driving unit comprises a first electrode disposed on the membrane and a second electrode disposed on the substrate.

45. The method of claim 44, wherein the acoustic transducer further comprises:
a power source;
a first wiring which is electrically connected to the second electrode of the first electrostatic driving unit, the first electrode of the second electrostatic driving unit, and a first end of the power source; and
a second wiring which is electrically connected to the first electrode of the first electrostatic driving unit, the second electrode of the second electrostatic driving unit, and a second end of the power source.

46. The method of claim 44, wherein
the acoustic transducer further comprises a phase inversion circuit,
one of the first electrode of the first electrostatic driving unit and the first electrode of the second electrostatic driving unit is connected to the phase inversion circuit; and
the second electrode of the first electrostatic driving unit and the second electrode of the second electrostatic driving unit together comprise a single a common electrode disposed on the substrate.

47. The method of claim 26, wherein the first driving unit group comprises a first number of driving units and the second driving unit group comprises a second number of driving units different from the first number.
